(19) United States
(12) Patent Application Publication
(10) Pub. No.: US 2023/0006109 A1
(43) Pub. Date: Jan. 5, 2023

(54) LIGHT EMITTING DEVICE AND MANUFACTURING METHOD THEREOF

(71) Applicant: Genesis Photonics Inc., Tainan City (TW)

(72) Inventors: Yun-Han Wang, Tainan City (TW); Chin-Hua Hung, Tainan City (TW); Chuan-Yu Liu, Tainan City (TW); Tsai-Chieh Shih, Tainan City (TW); Jui-Fu Chang, Tainan City (TW); Yu-Jung Wu, Tainan City (TW); Yu-Feng Lin, Tainan City (TW)

(73) Assignee: Genesis Photonics Inc., Tainan City (TW)

(21) Appl. No.: 17/848,408

(22) Filed: Jun. 24, 2022

Related U.S. Application Data
(63) Continuation-in-part of application No. 17/164,725, filed on Feb. 1, 2021.
Application No. 17/164,725 is a continuation of application No. 16/004,445, filed on Jun. 11, 2018, now Pat. No. 10,910,523.
Application No. 16/004,445 is a division of application No. 15/268,654, filed on Sep. 19, 2016, now Pat. No. 9,997,676.
Application No. 15/268,654 is a continuation-in-part of application No. 14/711,798, filed on May 14, 2015, now abandoned.
(60) Provisional application No. 63/214,772, filed on Jun. 24, 2021.
(60) Provisional application No. 62/157,450, filed on May 5, 2015.
(60) Provisional application No. 62/220,249, filed on Sep. 18, 2015.
(60) Provisional application No. 62/236,150, filed on Oct. 2, 2015.
(60) Provisional application No. 62/245,247, filed on Oct. 22, 2015.
(60) Provisional application No. 62/262,876, filed on Dec. 3, 2015.

(30) Foreign Application Priority Data
May 14, 2014 (TW) 103116987
Jan. 8, 2016 (TW) 105100499
May 5, 2016 (CN) 201610293182.5

(51) Int. Cl. H01L 33/50; H01L 33/46; H01L 33/38; H01L 33/56; H01L 21/56; H01L 23/00; H01L 21/683

(52) U.S. Cl. CPC H01L 33/502; H01L 33/46; H01L 33/38; H01L 33/56; H01L 33/50; H01L 21/56; H01L 24/20; H01L 21/561; H01L 24/32; H01L 24/19; H01L 24/96; H01L 21/6835; H01L 2933/0016; H01L 2933/0041; H01L 2933/0025; H01L 2933/005; H01L 21/568; H01L 2224/04105; H01L 2224/32225; H01L 2224/73267; H01L 2224/96; H01L 2224/97; H01L 2924/18162; H01L 2924/12041; H01L 25/0753

(57) ABSTRACT

A light emitting device and a manufacturing method thereof are provided. The light emitting device includes a light emitting unit, a fluorescent layer, a reflective layer, and a light-absorbing layer. The light emitting unit has a top surface, a bottom surface opposite to the top surface, and a side surface located between the top surface and the bottom surface. The light emitting unit includes an electrode disposed at the bottom surface. The fluorescent layer is disposed on the top surface of the light emitting unit. The reflective layer covers the side surface of the light emitting unit. The light-absorbing layer covers the reflective layer, so that the reflective layer is located between the side surface of the light emitting unit and the light-absorbing layer.

### CROSS-REFERENCE TO RELATED APPLICATION

This application claims the priority benefit of U.S. provisional application Ser. No. 63/214,772, filed on Jun. 24, 2021. This application is also a continuation-in-part application of and claims the priority benefit of U.S. application Ser. No. 17/164,725, filed on Feb. 1, 2021, now pending. The prior U.S. application Ser. No. 17/164,725 is a continuation application of and claims the priority benefit of U.S. patent application Ser. No. 16/004,445, filed on Jun. 11, 2018, now patented. The prior U.S. patent application Ser. No. 16/004,445 is a divisional application of and claims the priority benefit of U.S. patent application Ser. No. 15/268,654, filed on Sep. 19, 2016, now patented. The prior U.S. patent application Ser. No. 15/268,654 is a continuation-in-part application of and claims the priority benefit of U.S. application Ser. No. 14/711,798, filed on May 14, 2015, now abandoned, which claims the priority benefits of Taiwan application serial no. 103116987, filed on May 14, 2014 and U.S. provisional application Ser. No. 62/157,450, filed on May 5, 2015. The prior U.S. patent application Ser. No. 15/268,654 also claims the priority benefits of U.S. provisional application Ser. No. 62/220,249, filed on Sep. 18, 2015, U.S. provisional application Ser. No. 62/236,150, filed on Oct. 2, 2015, Taiwan application serial no. 105100499, filed on Jan. 8, 2016, U.S. provisional application Ser. No. 62/245,247, filed on Oct. 22, 2015, U.S. provisional application Ser. No. 62/262,876, filed on Dec. 3, 2015 and China application serial no. 201610293182.5, filed on May 5, 2016. The entirety of each of the above-mentioned patent applications is hereby incorporated by reference herein and made a part of this specification.

### BACKGROUND

### Technical Field

The invention relates to a light emitting device and a manufacturing method thereof, and more particularly, to a light emitting package device for which an LED is used as the light source and a manufacturing method thereof.

### Description of Related Art

In a light emitting package device made of light emitting diode chips, since the package material (such as a white reflective layer) has light transmittance, unwanted light leakage occurs in a specific position or direction, so that the light emitting package device, for example, in the application of backlight, reduces the contrast of the display screen, thus affecting the display quality.

### SUMMARY

The invention provides a light emitting unit having better light emitting quality.

A light emitting device of the invention includes a light emitting unit, a fluorescent layer, a reflective layer, and a light-absorbing layer. The light emitting unit has a top surface, a bottom surface opposite to the top surface, and a side surface located between the top surface and the bottom surface. The light emitting unit includes an electrode disposed at the bottom surface. The fluorescent layer is disposed on the top surface of the light emitting unit. The reflective layer covers the side surface of the light emitting unit. The light-absorbing layer covers the reflective layer, so that the reflective layer is located between the side surface of the light emitting unit and the light-absorbing layer.

Based on the above, the light emitting unit of the invention has better light emitting quality.

The invention provides a manufacturing method of a light emitting unit, and the resulting light emitting device has better light emitting quality.

A manufacturing method of a light emitting device of the invention includes the following steps: providing a light emitting unit having a top surface, a bottom surface opposite to the top surface, and a side surface located between the top surface and the bottom surface, and the light emitting unit includes an electrode disposed at the bottom surface; disposing the light emitting unit on a fluorescent material, so that the top surface of the light emitting unit faces the fluorescent material; forming a reflective layer covering the side surface of the light emitting unit; and forming a light-absorbing layer to cover the reflective layer, so that the reflective layer is located between the side surface of the light emitting unit and the light-absorbing layer.

Based on the above, the light emitting device manufactured by the manufacturing method of the light emitting device of the invention has better light emitting quality.

### BRIEF DESCRIPTION OF THE DRAWINGS

FIG. 1A to FIG. 1I are schematic partial cross-sectional views of a portion of a manufacturing method of a light emitting device according to the first embodiment of the invention.

FIG. 1J is a schematic partial cross-sectional view of a light emitting device according to the first embodiment of the invention.

FIG. 2 is a schematic partial cross-sectional view of a light emitting device according to the second embodiment of the invention.

FIG. 3A to FIG. 3C are schematic partial cross-sectional views of a portion of a manufacturing method of a light emitting device according to the third embodiment of the invention.

FIG. 3D is a schematic partial cross-sectional view of a light emitting device according to the third embodiment of the invention.

FIG. 4 is a schematic partial cross-sectional view of a light emitting device according to the fourth embodiment of the invention.

FIG. 5A to FIG. 5D are schematic partial cross-sectional views of a portion of a manufacturing method of a light emitting device according to the fifth embodiment of the invention.

FIG. 5E is a schematic partial cross-sectional view of a light emitting device according to the fifth embodiment of the invention.

FIG. 6 is a schematic partial cross-sectional view of a light emitting device according to the sixth embodiment of the invention.

FIG. 7A to FIG. 7C are schematic partial cross-sectional views of a portion of a manufacturing method of a light emitting device according to the seventh embodiment of the invention.

FIG. 7D is a schematic partial cross-sectional view of a portion of a manufacturing method of a light emitting device according to the seventh embodiment of the invention.

FIG. 8 is a schematic partial cross-sectional view of a light emitting device according to the eighth embodiment of the invention.

FIG. 9A to FIG. 9F are schematic partial cross-sectional views of a portion of a manufacturing method of a light emitting device according to the ninth embodiment of the invention.

FIG. 9G is a schematic partial cross-sectional view of a light emitting device according to the ninth embodiment of the invention.

FIG. 10 is a schematic partial cross-sectional view of a light emitting device according to the tenth embodiment of the invention.

FIG. 11A to FIG. 11D are schematic partial cross-sectional views of a portion of a manufacturing method of a light emitting device according to the eleventh embodiment of the invention.

FIG. 11E is a schematic partial cross-sectional view of a light emitting device according to the eleventh embodiment of the invention.

FIG. 12 is a schematic partial cross-sectional view of a light emitting device according to the twelfth embodiment of the invention.

### DESCRIPTION OF THE EMBODIMENTS

Unless expressly stated otherwise, directional terms (e.g., above, below, top, or bottom) used herein are used only with reference to the drawings and are not intended to imply absolute orientation.

Unless explicitly stated otherwise, any method described herein is in no way intended to be construed as requiring that its steps be performed in a particular order.

As used herein, the singular forms “a” or “the” include plural counterparts unless the context clearly dictates otherwise.

The invention is more comprehensively described with reference to the figures of the present embodiments. However, the invention may also be implemented in various different forms, and is not limited to the embodiments in the present specification. The thicknesses of the layers and regions in the figures are enlarged for clarity. The same or similar reference numerals represent the same or similar elements and are not repeated in the following paragraphs.

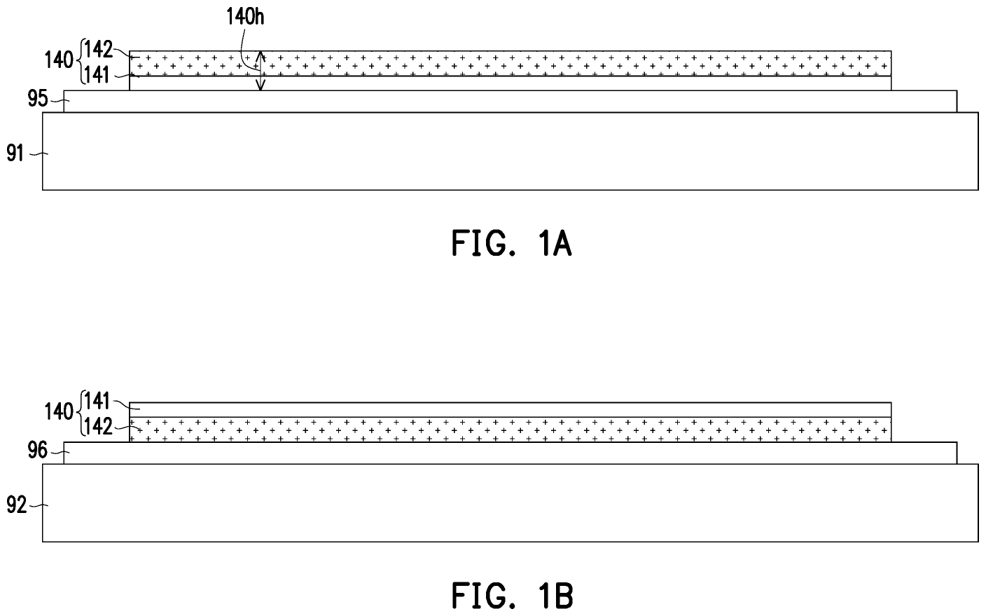

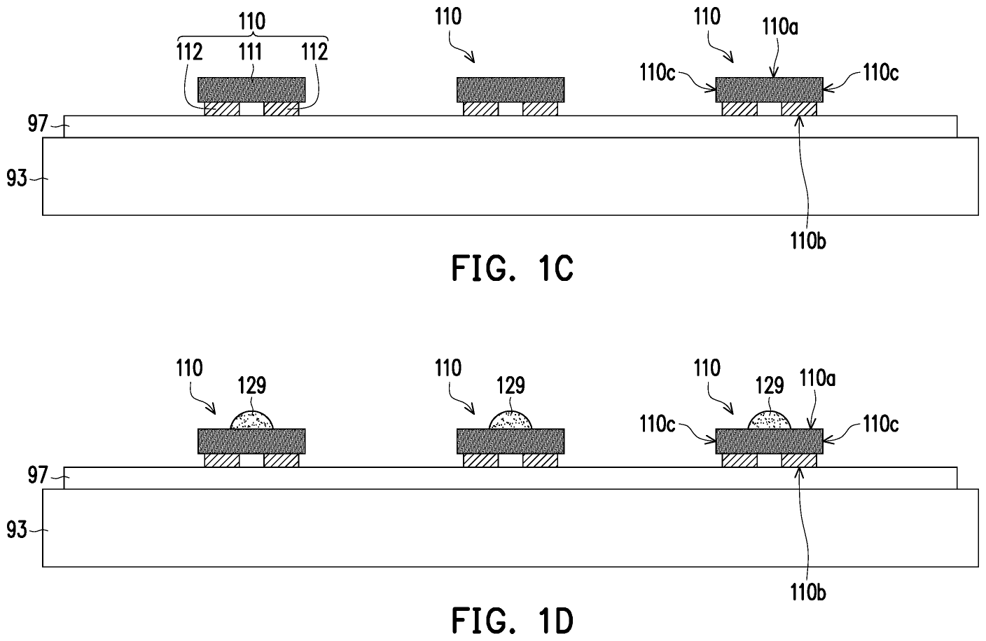

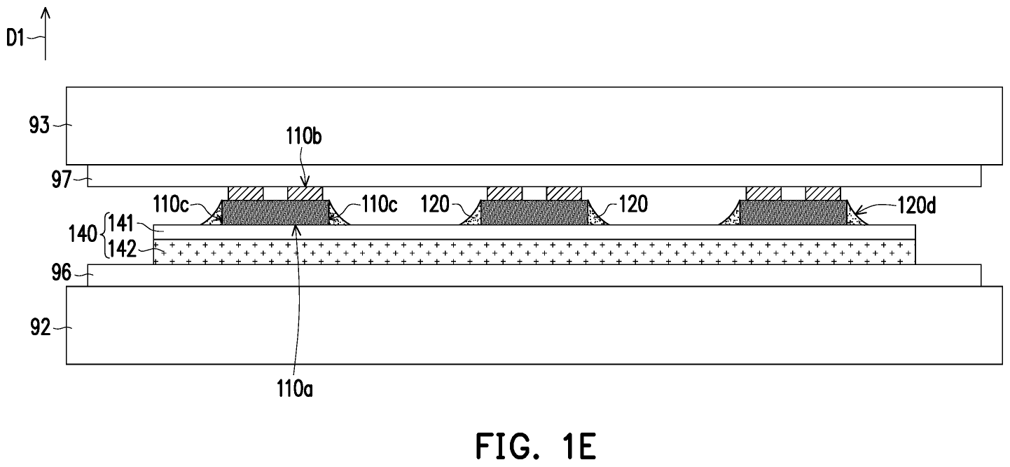

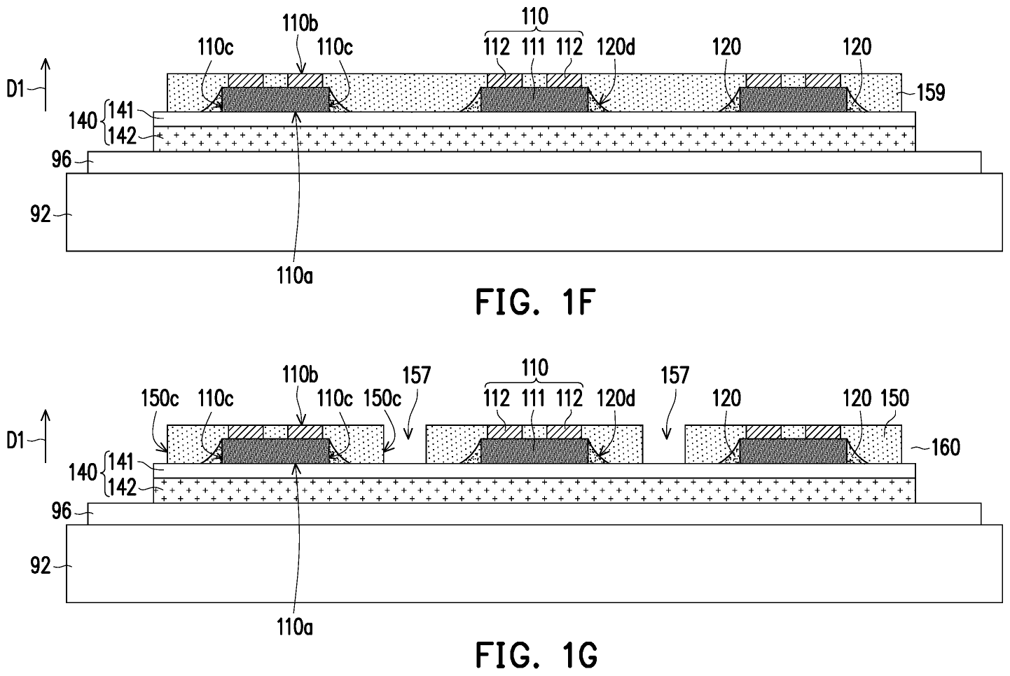

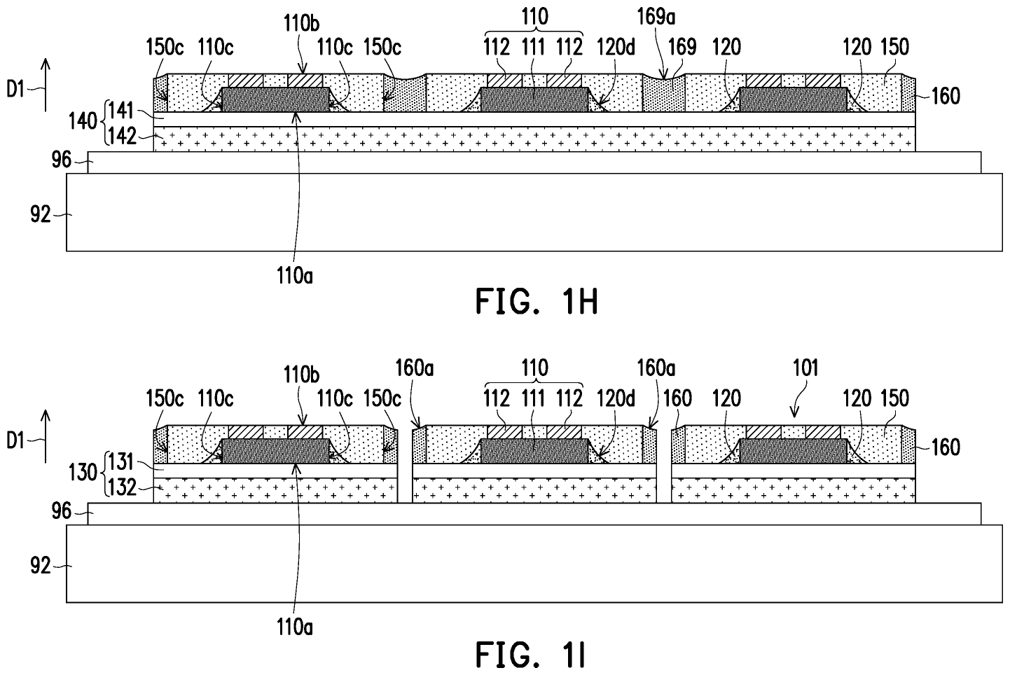

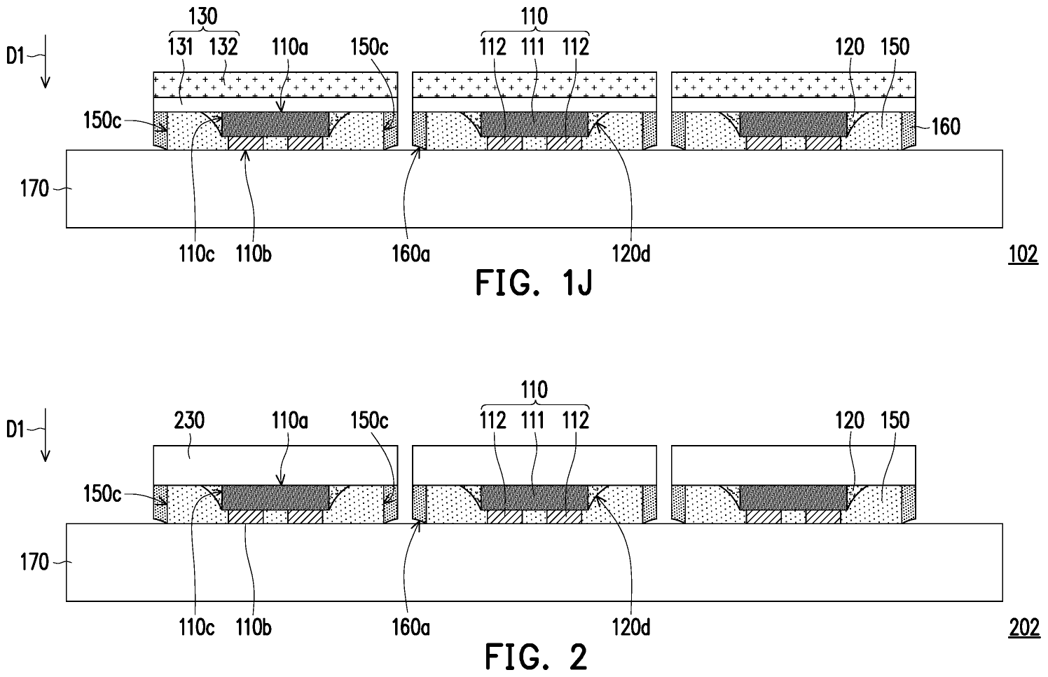

FIG. 1A to FIG. 1I are schematic partial cross-sectional views of a portion of a manufacturing method of a light emitting device according to the first embodiment of the invention.

Referring to FIG. 1A, a fluorescent material 140 is provided.

In an embodiment, the fluorescent material 140 is formed on a carrier board 91, and the surface of the carrier board 91 suitable for forming the fluorescent material 140 has a release film 95, but the invention is not limited thereto. For example, a fluorescent colloid is first formed on the carrier board 91 by mixing phosphor and colloid (e.g., silicone). And, after the fluorescent colloid is cured, the film-shaped or sheet-shaped fluorescent material 140 is formed. The phosphor includes an up-conversion material, a down-conversion material, or a quantum dot, but the invention is not limited thereto.

In an embodiment, during the process of placing the fluorescent colloid at rest, most of the phosphor in the fluorescent colloid tends to be downward (here: downward in the direction of gravity) due to gravity. As a result, the phosphor concentration of the region below the fluorescent colloid is greater than the phosphor concentration of the region above the fluorescent colloid. That is, the fluorescent material 140 is regarded as including a low-concentration fluorescent material 142 and a high-concentration fluorescent material 141 stacked on each other.

In an embodiment, a thickness 140h of the entire fluorescent material 140 is, for example, 130 micrometers (μm), but the invention is not limited thereto.

Referring to FIG. 1A to FIG. 1B, in an embodiment, after the fluorescent material 140 is formed on the carrier board 91 (shown in FIG. 1A), the phosphor 140 is placed on another carrier board 92 (shown in FIG. 1B) by suitable transposition. A release film 96 is provided on the surface of the carrier board 92 suitable for placing the fluorescent material 140, but the invention is not limited thereto.

Referring to FIG. 1C, light emitting units 110 are provided. Each of the light emitting units 110 includes a corresponding light emitting diode chip 111 and corresponding electrodes 112. The electrodes 112 are disposed at a bottom surface 110b of the light emitting unit 110, and the corresponding electrodes 112 are electrically connected to the corresponding semiconductor layers in the light emitting diode chip 111.

In an embodiment, the light emitting units 110 are placed on a carrier board 93. A release film 97 is provided on the surface of the carrier board 93 suitable for placing the light emitting units 110, but the invention is not limited thereto. The number and corresponding positions of the light emitting units 110 placed on the carrier board 93 are adjusted according to design requirements, and are not limited in the invention. In order to improve the throughput of the process, the number of the light emitting units 110 placed on the carrier board 93 may be a plurality.

Referring to FIG. 1C to FIG. 1D, an adhesive material 129 is formed on a top surface 110a (i.e., a surface opposite to the bottom surface 110b) of the light emitting units 110. The material of the adhesive material 129 may be light-transmitting (e.g., silicone), and the adhesive material 129 is formed on the top surface 110a of the light emitting units 110 by dispensing.

Referring to FIG. 1B and FIG. 1D to FIG. 1E, the light emitting units 110 are disposed on the fluorescent material 140. For example, the light emitting units 110 are bonded to the fluorescent material 140 via the adhesive material 129 located on the light emitting units 110.

In an embodiment, after the light emitting units 110 and the fluorescent material 140 are bonded, the colloid forming a portion of the adhesive material 129 overflows to a side surface 110c (i.e., a surface located between the top surface 110a and the bottom surface 110b) of the light emitting units 110 due to being squeezed. In addition, due to surface tension, the colloid overflowing on the side surface 110c of the light emitting units 110 has a curved slope, and the thickness of the colloid located on the side surface 110c of the light emitting units 110 is gradually increased toward the light emitting units 110. That is to say, the thickness of the adhesive material located on the side surface 110c of the light emitting units 110 is gradually increased toward the light emitting units 110.

In an embodiment, after the light emitting units 110 and the fluorescent material 140 are bonded, there is still a portion of the adhesive material between the top surface 110a of the light emitting units 110 and the fluorescent material 140, but the invention is not limited thereto. In an embodiment, after the light emitting units 110 and the fluorescent material 140 are bonded, the top surface 110a of the light emitting units 110 is directly contact with the fluorescent material 140.

In an embodiment, after the light emitting units 110 and the fluorescent material 140 are bonded, the adhesive material is cured (e.g., heated and/or illuminated) at a suitable time and in a suitable manner. The cured adhesive material is called an adhesive layer 120. The adhesive layer 120 located on the side surface 110c of the light emitting units 110 has an inwardly inclined curved surface 120d, and/or the thickness of the adhesive layer 120 located on the side surface 110c of the light emitting units 110 is gradually increased toward the light emitting units 110.

Referring to FIG. 1E to FIG. 1F, a reflective material 159 is formed on the fluorescent material 140 to cover the light emitting units 110.

In an embodiment, the material of the reflective material 159 includes, for example, white adhesive (e.g., polyvinyl acetate (PVA)). In an embodiment, the material of the reflective material 159 is, for example, a colloid (e.g., silicone) and reflective particles (e.g., titanium dioxide particles) mixed therein. In an embodiment, the material of the reflective material 159 is partially transparent, and the refractive index of the cured reflective material 159 is less than the refractive index of the adhesive layer 120 to form a corresponding total reflection interface.

In an embodiment, the carrier board 93 is removed first, and then the reflective material 159 covering the light emitting units 110 is formed on the fluorescent material 140. Moreover, if (but not limited to) the reflective material 159 covers the bottom end of the electrodes 112 of the light emitting units 110 (for example, where the electrodes 112 are farthest from the light emitting diode chip 111 in the thickness direction of the light emitting units 110), the reflective material 159 may be removed by a suitable method (e.g., scraping; or grinding, cutting, or etching) at a suitable time (e.g., before the reflective material 159 is cured; or after the reflective material 159 is cured).

In an embodiment, the reflective material 159 covering the light emitting units 110 is formed on the fluorescent material 140 (e.g., via a filling process between two plates) first, and then the carrier board 93 is removed.

Referring to FIG. 1F to FIG. 1G, a portion of the reflective material 159 (labeled in FIG. 1F) is removed to form grooves 157 exposing a portion of the fluorescent material 140, and form a reflective layer 150 (labeled in FIG. 1G) corresponding to and covering the light emitting units 110. For example, the partially reflective material 159 located between two adjacent light emitting units 110 is removed by a suitable method (e.g., cutting or etching).

In the present embodiment, the grooves 157 expose a portion of the high-concentration fluorescent material 141.

In an embodiment not shown, during the process of removing a portion of the reflective material 159, a portion of the high-concentration fluorescent material 141 (e.g., a portion of the high-concentration fluorescent material 141 near where the reflective material 159 is removed) is slightly removed.

In the present embodiment, the grooves 157 formed by the steps of FIG. 1F to FIG. 1G do not substantially expose a portion of the low-concentration fluorescent material 142, but the invention is not limited thereto.

Referring to FIG. 1G to FIG. 1H, a light-absorbing material 169 is formed to cover at least a side surface 150c of the reflective layer 150. The light-absorbing material 169 includes, for example, a colloid (e.g., silicone) and a light-absorbing material mixed therein (e.g., carbon black, black dye, dark dye, black pigment, or dark pigment), but the invention is not limited thereto.

In an embodiment, when or after the colloid forming the light-absorbing material 169 is covered on the side surface 150c of the reflective layer 150, due to surface tension, the thickness of the colloid located on the side surface 150c of the reflective layer 150 is gradually increased toward the reflective layer 150. That is, the thickness of the light-absorbing material 169 located on the side surface 150c of the reflective layer 150 is gradually increased toward the corresponding reflective layer 150.

In an embodiment, the light-absorbing material 169 is formed in the grooves 157 (labeled in FIG. 1G). That is, the light-absorbing material 169 is formed between two adjacent reflective layers 150 or two adjacent light emitting units 110. Also, the light-absorbing material 169 located in the grooves has a corresponding inwardly concave outer surface 169a. The inwardly concave outer surface 169a is inwardly concave in the direction of the fluorescent material 140.

In an embodiment, the inwardly concave curvature of the inwardly concave outer surface 169a is correspondingly adjusted by the amount of adhesive, adhesive concentration, and/or adhesive viscosity, but the invention is not limited thereto.

Referring to FIG. 1H to FIG. 1I, a portion of the light-absorbing material 169 (labeled in FIG. 1H), a portion of the high-concentration fluorescent material 141 (labeled in FIG. 1H, a portion of the fluorescent material 140), and a portion of the low-concentration fluorescent material 142 (labeled in FIG. 1H, a portion of the fluorescent material 140) are removed to correspondingly form a light-absorbing layer 160 (labeled in FIG. 1I), a high-concentration fluorescent layer 131 (labeled in FIG. 1I, a portion of a fluorescent layer 130), and a low-concentration fluorescent layer 132 (labeled in FIG. 1I, a portion of the fluorescent layer 130). For example, a portion of the light-absorbing material 169 located between two adjacent light emitting units 110 and the corresponding fluorescent material 140 are removed by a suitable method (e.g., cutting or etching). That is, the removed portion of the light-absorbing material 169 and the portion of the fluorescent material 140 at least correspond to the inwardly concave outer surface 169a. In an embodiment, the above steps are referred to as a singulation process.

After the above process, the manufacture of a light emitting device 101 of the first embodiment may be substantially completed.

Referring to FIG. 1I, the light emitting device 101 includes the light emitting units 110, the fluorescent layer 130, the reflective layer 150, and the light-absorbing layer 160. The light emitting units 110 have the top surface 110a, the bottom surface 110b, and the side surface 110c. The bottom surface 110b is opposite to the top surface 110a. The side surface 110c is located between the top surface 110a and the bottom surface 110b. The light emitting units 110 include the electrodes 112 disposed at the bottom surface 110b. The fluorescent layer 130 is disposed on the top surface 110a of the light emitting units 110. The reflective layer 150 covers the side surface 110c of the light emitting units 110. The light-absorbing layer 160 covers the reflective layer 150. The reflective layer 150 is located between the side surface 110c of the light emitting units 110 and the light-absorbing layer 160.

In the present embodiment, the bottom end (for example: in a thickness direction D1 of the light emitting device 101, where the light-absorbing layer 160 is farthest from the fluorescent layer 130) of the light-absorbing layer 160 is aligned (for example: located on a same horizontal plane, and the thickness direction D1 is substantially the normal direction of the horizontal plane) with the bottom end (for example: in the thickness direction D1 of the light emitting device 101, where the electrodes 112 are farthest from the fluorescent layer 130) of the electrodes 112 of the light emitting units 110.

In the present embodiment, the bottom of the light-absorbing layer 160 has an inwardly concave curved surface 160a, and the inwardly concave curved surface 160a is concave toward the fluorescent layer 130 along a direction away from the light emitting units 11.

In the present embodiment, in the thickness direction D1 of the light emitting device 101, the thickness of the light-absorbing layer 160 is gradually decreased along the direction away from the light emitting units 110 or the reflective layer 150.

In the present embodiment, the light emitting device 101 further includes an adhesive layer 120. The adhesive layer 120 covers the side surface 110c of the light emitting units 110. The adhesive layer 120 is located between the side surface 110c of the light emitting units 110 and the reflective layer 150.

In the present embodiment, the light-absorbing layer 160 of the light emitting device 101 enables the light emitting device 101 to have better applicability.

In an embodiment, the light emitting device 101 is adaptively applied. Taking FIG. 1I and FIG. 1J as examples, by means of a suitable device (e.g., pick up and place device) or method (e.g., pick up and place process), the light emitting device 101 is picked up from the carrier board 92 and placed on the circuit board 170, and the electrodes 112 of the light emitting units 110 are electrically connected to the circuit board 170, which is regarded as another form of a light emitting device 102 in the first embodiment (labeled in FIG. 1J). In other words, when understanding the light emitting device 102 in FIG. 1J, refer to the light emitting device 101 in FIG. 1I and its corresponding description or manufacturing method (e.g., FIG. 1A to FIG. 1I).

Referring to FIG. 1J, the light emitting device 102 includes the light emitting units 110, the fluorescent layer 130, the reflective layer 150, the light-absorbing layer 160, and the circuit board 170. The bottom surface 110b of the light emitting unit 110 faces the circuit board 170, and the electrodes 112 of the light emitting units 110 are electrically connected to corresponding circuits (not directly shown) in the circuit board 170.

In the present embodiment, in the thickness direction D1 of the light emitting device 102, the spacing between the light-absorbing layer 160 and the circuit board 170 is gradually increased in a direction away from the light emitting units 110 or the reflective layer 150.

In the present embodiment, via the light-absorbing layer 160, the electrical connection yield between the electrodes 112 of the light emitting units 110 and the circuit board 170 is improved, thereby improving the light output quality of the light emitting device 102.

In the present embodiment, the light emitting quality of the light emitting device 101 or the light emitting device 102 is improved via the light-absorbing layer 160. For example, lateral light output is reduced; and/or light mixing phenomenon is reduced.

FIG. 2 is a schematic partial cross-sectional view of a light emitting device according to the second embodiment of the invention. The manufacturing method of a light emitting device 202 of the present embodiment is similar to the manufacturing method of the light emitting device (e.g., the light emitting device 102) in the above embodiment, and similar members thereof are represented by the same reference numerals and have similar functions, materials, or forming methods, and are not repeated herein.

Referring to FIG. 2, the light emitting device 202 includes the light emitting units 110, a fluorescent layer 230, the reflective layer 150, and the light-absorbing layer 160. The fluorescent layer 230 is disposed on the top surface 110a of the light emitting units 110.

In the present embodiment, the fluorescent layer 230 is a single film layer, and/or the phosphor concentration of each portion of the fluorescent layer 230 is substantially the same or similar.

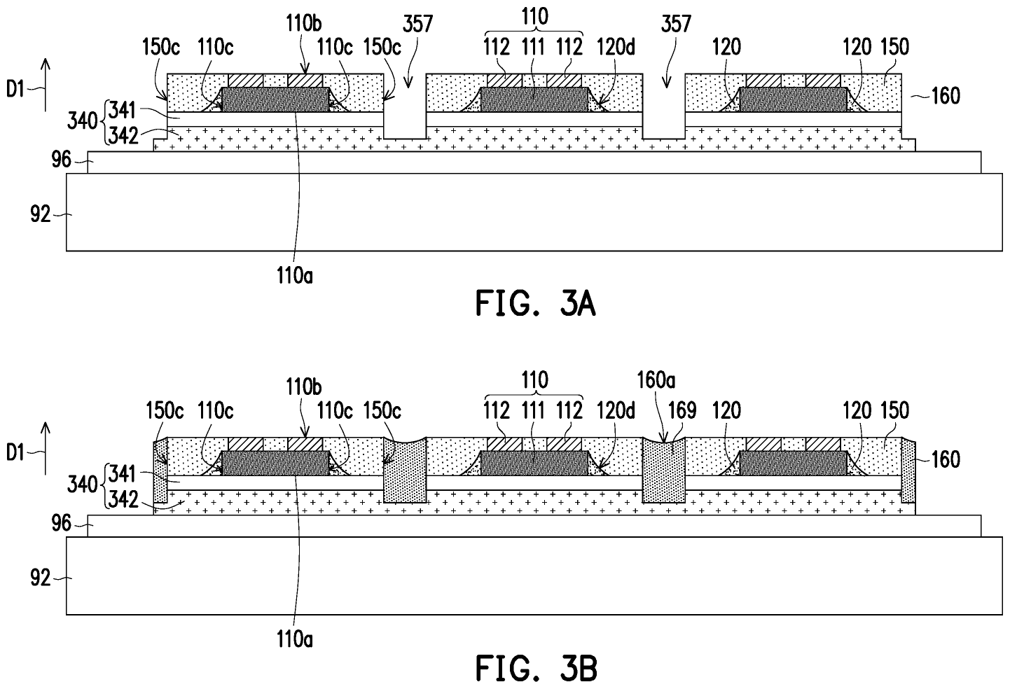

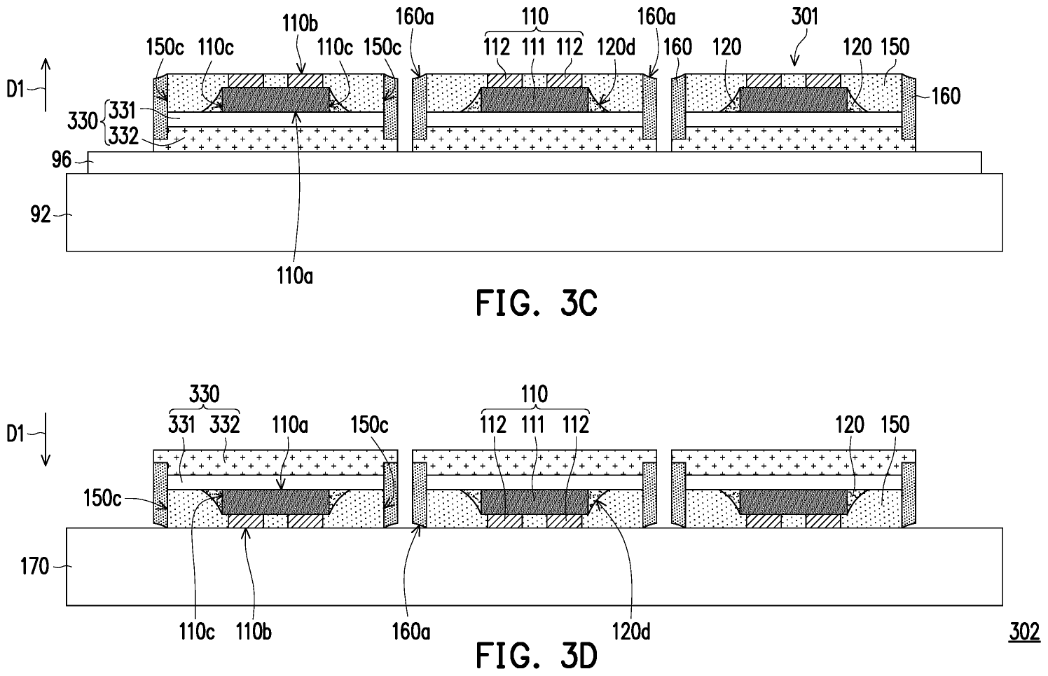

FIG. 3A to FIG. 3D are schematic partial cross-sectional views of a portion of a manufacturing method of a light emitting device according to the third embodiment of the invention. The manufacturing method of a light emitting device 301 of the present embodiment is similar to the manufacturing method of the light emitting device (e.g., the light emitting device 101) in the above embodiments, and similar members thereof are represented by the same reference numerals and have similar functions, materials, or forming methods, and are not repeated herein. Specifically, FIG. 3A to FIG. 3D show schematic partial cross-sectional views illustrating a portion of a manufacturing method of a light emitting device following the step of FIG. 1F.

Referring to FIG. 1F and FIG. 3A, a portion of the reflective material 159 (labeled in FIG. 1F) and a portion of the fluorescent material 140 (labeled in FIG. 1F) are removed to form grooves 357 exposing a portion of a fluorescent material 340, and to form the reflective layer 150 (labeled in FIG. 3A) corresponding to and covering the light emitting units 110. For example, a portion of the reflective material 159 located between two adjacent light emitting units 110 and the corresponding fluorescent material 140 may be removed by a suitable method (e.g., cutting or etching).

In the present embodiment, the fluorescent material 340 includes a low-concentration fluorescent material 342 and a high-concentration fluorescent material 341, and the grooves 357 expose a portion of the low-concentration fluorescent material 342.

Referring to FIG. 3A to FIG. 3B, similar to the steps of FIG. 1G to FIG. 1H, the light-absorbing material 169 is formed to cover at least the side surface 150c of the reflective layer 150.

Please refer to FIG. 3B to FIG. 3C, similar to the steps of FIG. 1H to FIG. 1I above, a portion of the light-absorbing material 169 (labeled in FIG. 3B) and a portion of the low-concentration fluorescent material 342 (labeled in FIG. 3B, a portion of the fluorescent material 340) are removed to correspondingly form the light-absorbing layer 160 (labeled in FIG. 3C) and a low-concentration fluorescent layer 332 (labeled in FIG. 3C, a portion of a fluorescent layer 330). The high-concentration fluorescent material 341 (labeled in FIG. 3B, a portion of the fluorescent material 340) is directly regarded as a high-concentration fluorescent layer 331 (labeled in FIG. 3C, a portion of the fluorescent layer 330).

After the above process, the manufacture of the light emitting device 301 of the third embodiment may be substantially completed.

Referring to FIG. 3C, the light emitting device 301 includes the light emitting units 110, the fluorescent layer 330, the reflective layer 150, and the light-absorbing layer 160. The fluorescent layer 330 is disposed on the top surface 110a of the light emitting units 110.

Referring to FIG. 3D, similar to that shown in FIG. 1J, in an embodiment, the electrodes 112 of the light emitting units 110 are electrically connected to the circuit board 170, which is regarded as another form of a light emitting device 302 (labeled in FIG. 3D) in the third embodiment. In other words, when understanding the light emitting device 302 in FIG. 3D, refer to the light emitting device 301 in FIG. 3C and its corresponding description or manufacturing method (e.g., FIG. 1A to FIG. 1F and FIG. 3A to FIG. 3C).

Referring to FIG. 3D, the light emitting device 302 includes the light emitting units 110, the fluorescent layer 330, the reflective layer 150, the light-absorbing layer 160, and the circuit board 170.

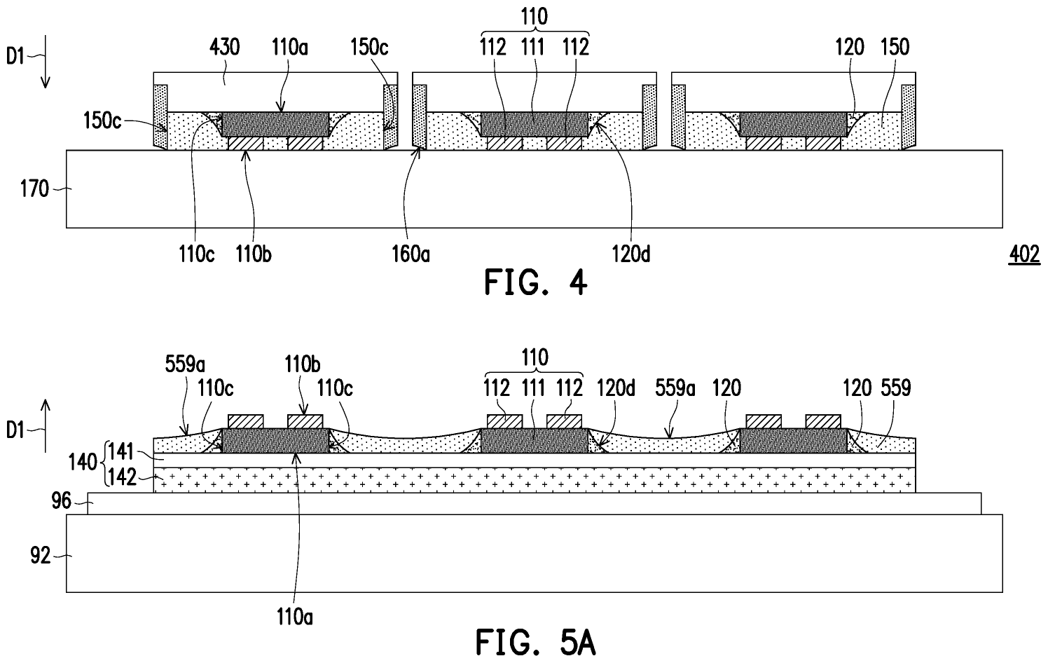

FIG. 4 is a schematic partial cross-sectional view of a light emitting device according to the fourth embodiment of the invention. The manufacturing method of a light emitting device 402 of the present embodiment is similar to the manufacturing method of the light emitting device (e.g., the light emitting devices 202 and 302, but not limited to) in the above embodiments, and similar members thereof are represented by the same reference numerals and have similar functions, materials, or forming methods, and are not repeated herein.

Referring to FIG. 4, the light emitting device 402 includes the light emitting units 110, the fluorescent layer 430, the reflective layer 150, and the light-absorbing layer 160. The fluorescent layer 430 is disposed on the top surface 110a of the light emitting units 110.

In the present embodiment, the fluorescent layer 430 is a single film layer, and/or the phosphor concentration of each portion of the fluorescent layer 430 is substantially the same or similar.

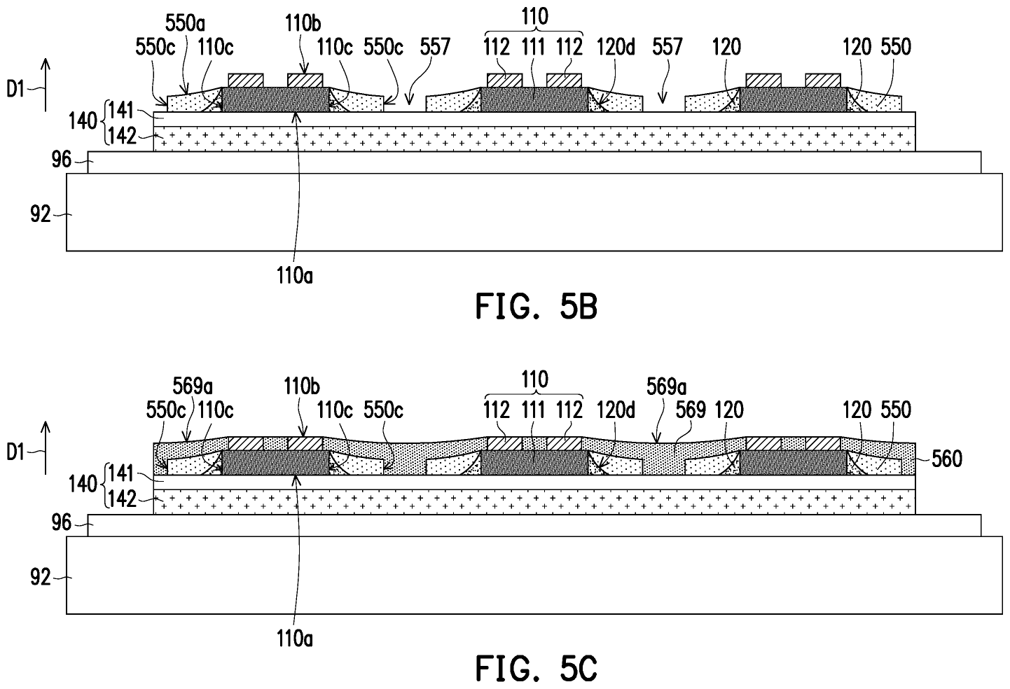

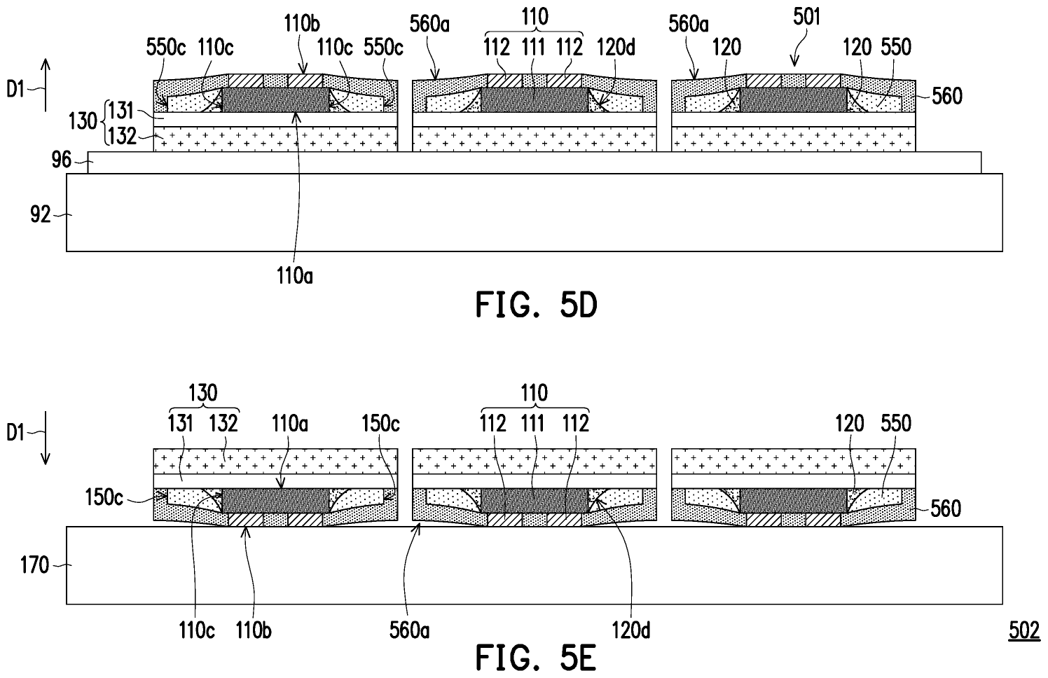

FIG. 5A to FIG. 5E are schematic partial cross-sectional views of a portion of a manufacturing method of a light emitting device according to the fifth embodiment of the invention. The manufacturing method of a light emitting device 501 of the present embodiment is similar to the manufacturing method of the light emitting device (e.g., the light emitting device 101, but not limited to) in the above embodiments, and similar members thereof are represented by the same reference numerals and have similar functions, materials, or forming methods, and are not repeated herein. Specifically, FIG. 5A to FIG. 5E show schematic partial cross-sectional views illustrating a portion of a manufacturing method of the light emitting device 101 following the step of FIG. 1E.

Referring to FIG. 1E and FIG. 5A, a reflective material 559 is formed on the fluorescent material 140 to cover the light emitting units 110. The material or the forming method of the reflective material 559 is the same as or similar to the reflective material 159.

In an embodiment, when or after the colloid forming the reflective material 559 is directly or indirectly covered on the side surface 110c of the light emitting units 110, due to surface tension, the colloid located on the side surface 110c of the light emitting units 110 gradually approaches the fluorescent material 140 away from the light emitting units 110.

In an embodiment, the reflective material 559 is formed between two adjacent light emitting units 110. Also, the reflective material 559 located between the two light emitting units 110 has a corresponding inwardly concave outer surface 559a. The inwardly concave outer surface 559a is inwardly concave in the direction of the fluorescent material 140.

In an embodiment, the inwardly concave curvature of the inwardly concave outer surface 559a is correspondingly adjusted by the amount of adhesive, adhesive concentration, and/or adhesive viscosity, but the invention is not limited thereto.

In an embodiment, the reflective material 559 does not cover the electrodes 112 of the light emitting units 110.

Referring to FIG. 5A to FIG. 5B, similar to the steps of FIG. 1F to FIG. 1G, a portion of the reflective material 559 (labeled in FIG. 5A) is removed to form grooves 557 exposing a portion of the fluorescent material 140, and to form a reflective layer 550 (labeled in FIG. 5B) corresponding to and covering the light emitting units 110. For example, the partially reflective material 559 located between two adjacent light emitting units 110 is removed by a suitable method (e.g., cutting or etching).

In the present embodiment, the grooves 557 expose a portion of the high-concentration fluorescent material 141.

In the present embodiment, the grooves 557 formed by the steps of FIG. 5A to FIG. 5B do not substantially expose a portion of the low-concentration fluorescent material 142, but the invention is not limited thereto.

Referring to FIG. 5B to FIG. 5C, similar to the steps of FIG. 1G to FIG. 1H, a light-absorbing material 569 is formed to cover at least a side surface 550c and an inwardly concave curved surface 550a of the reflective layer 550. The material or the forming method of the light-absorbing material 569 is the same as or similar to the light-absorbing material 169.

In an embodiment, when or after the colloid forming the light-absorbing material 569 is covered on the reflective layer 550, due to surface tension, the colloid covering the reflective layer 550 gradually approaches the fluorescent material 140 away from the light emitting units 110.

In an embodiment, the light-absorbing material 569 is formed between two adjacent light emitting units 110. Also, the light-absorbing material 569 located between the two light emitting units 110 has a corresponding inwardly concave outer surface 569a. The inwardly concave outer surface 569a is inwardly concave in the direction of the fluorescent material 140.

Referring to FIG. 5C to FIG. 5D, similar to the steps of FIG. 1H to FIG. 1I above, a portion of the light-absorbing material 569 (labeled in FIG. 5C) and a portion of the fluorescent material 140 (labeled in FIG. 5C) are removed to correspondingly form a light-absorbing layer 560 (labeled in FIG. 5D) and the fluorescent layer 130 (labeled in FIG. 5D). A portion of a light-absorbing material 669 located between two adjacent light emitting units 110 and the corresponding fluorescent material 140 are removed by a suitable method (e.g., cutting or etching). That is, the removed portion of the light-absorbing material 669 and the portion of the fluorescent material 140 at least correspond to the inwardly concave outer surface 569a.

After the above process, the manufacture of the light emitting device 501 of the fifth embodiment may be substantially completed.

Referring to FIG. 5D, the light emitting device 501 includes the light emitting units 110, the fluorescent layer 130, the reflective layer 550, and the light-absorbing layer 560. The light-absorbing layer 560 covers the side surface 550c and the inwardly concave curved surface 550a of the reflective layer 550. The side surface 550c is substantially parallel to the thickness direction D1 of the light emitting device 101. The inwardly concave curved surface 550a is substantially not parallel to the thickness direction D1 of the light emitting device 101. The reflective layer 550 is located between the side surface 110c of the light emitting units 110 and a portion of the light-absorbing layer 560. The bottom of the light-absorbing layer 560 has an inwardly concave curved surface 560a, and the inwardly concave curved surface 560a is concave toward the fluorescent layer 130 along a direction away from the light emitting units 11.

In the present embodiment, the bottom end (for example: in the thickness direction D1 of the light emitting device 101, where the light-absorbing layer 560 is farthest from the fluorescent layer 130) of the light-absorbing layer 560 is aligned (for example: located on a same horizontal plane, and the thickness direction D1 is substantially the normal direction of the horizontal plane) with the bottom end (for example: in the thickness direction D1 of the light emitting device 101, where the electrodes 112 are farthest from the fluorescent layer 130) of the electrodes 112 of the light emitting units 110.

In the present embodiment, the bottom end of the reflective layer 550 (e.g., where the reflective layer 550 is farthest from the fluorescent layer 130 in the thickness direction D1 of the light emitting device 101) is not aligned with the bottom end of the electrodes 112 of the light emitting units 110.

Referring to FIG. 5E, similar to that shown in FIG. 1J, in an embodiment, the electrodes 112 of the light emitting units 110 are electrically connected to the circuit board 170, which is regarded as another form of a light emitting device 502 (labeled in FIG. 5E) in the fifth embodiment. In other words, when understanding the light emitting device 502 in FIG. 5E, refer to the light emitting device 501 in FIG. 5D and its corresponding description or manufacturing method (e.g., FIG. 1A to FIG. 1E and FIG. 5A to FIG. 5D).

Referring to FIG. 5E, the light emitting device 502 includes the light emitting units 110, the fluorescent layer 130, the reflective layer 550, the light-absorbing layer 560, and the circuit board 170.

In the present embodiment, in the thickness direction D1 of the light emitting device 502, the spacing between the reflective layer 550 and the circuit board 170 is gradually increased in a direction away from the light emitting units 110.

In the present embodiment, in the thickness direction D1 of the light emitting device 502, the spacing between the light-absorbing layer 560 and the circuit board 170 is gradually increased in a direction away from the light emitting units 110.

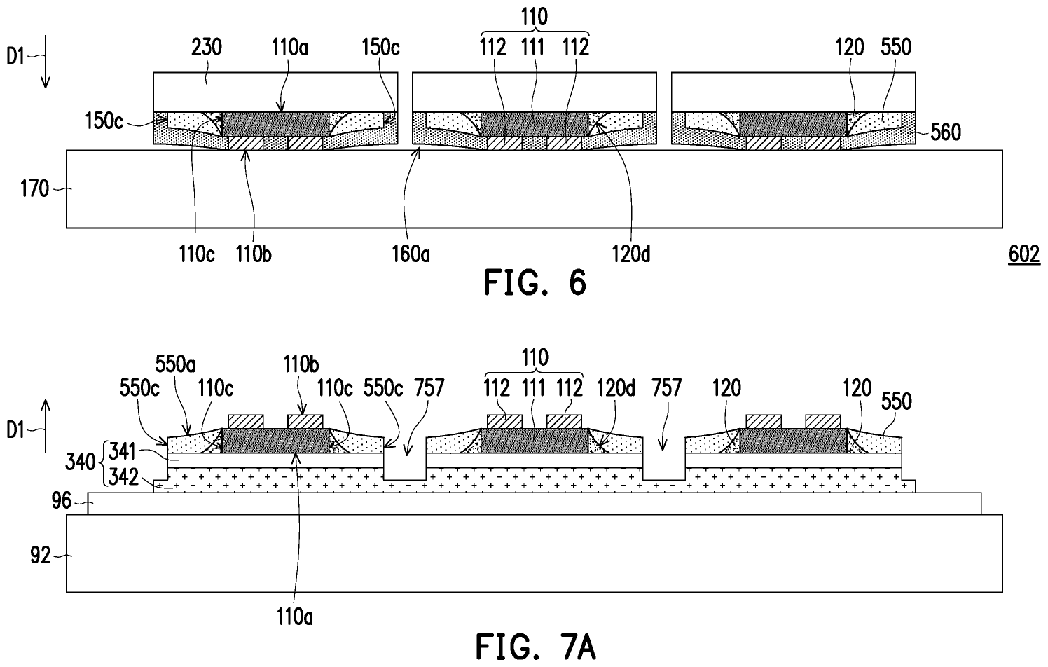

FIG. 6 is a schematic partial cross-sectional view of a light emitting device according to the sixth embodiment of the invention. The manufacturing method of a light emitting device 602 of the present embodiment is similar to the manufacturing method of the light emitting device (e.g., the light emitting devices 202 and 502, but not limited to) in the above embodiments, and similar members thereof are represented by the same reference numerals and have similar functions, materials, or forming methods, and are not repeated herein.

Referring to FIG. 6, the light emitting device 602 includes the light emitting units 110, the fluorescent layer 230, the reflective layer 550, and the light-absorbing layer 560.

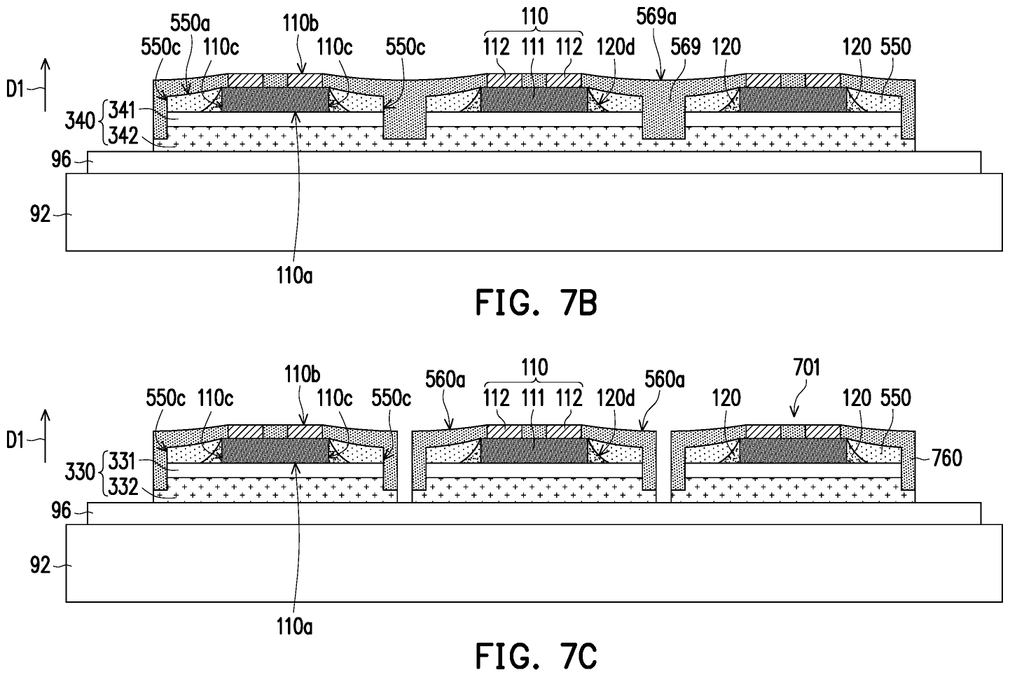

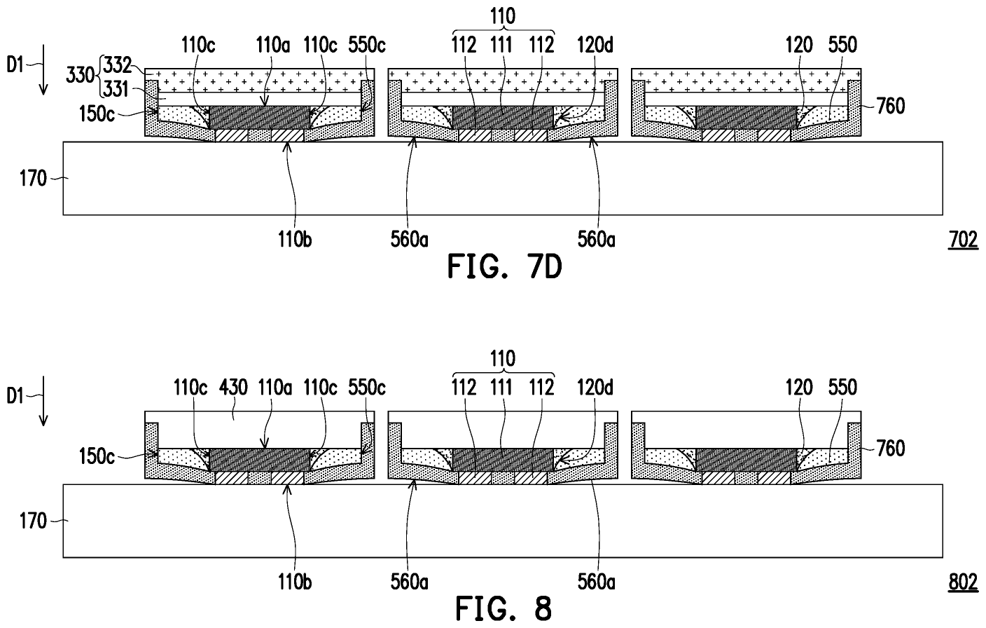

FIG. 7A to FIG. 7C are schematic partial cross-sectional views of a portion of a manufacturing method of a light emitting device according to the seventh embodiment of the invention. The manufacturing method of a light emitting device 701 of the present embodiment is similar to the manufacturing method of the light emitting device (e.g., the light emitting devices 101, 301, and 501, but not limited to) in the above embodiments, and similar members thereof are represented by the same reference numerals and have similar functions, materials, or forming methods, and are not repeated herein. For example, FIG. 7A to FIG. 7C show schematic partial cross-sectional views illustrating a partial manufacturing method of the light emitting device 701 following the steps of FIG. 1E and FIG. 5A.

Referring to FIG. 5A and FIG. 7A, similar to the steps of FIG. 1F and FIG. 3A, a portion of the reflective material 559 (labeled in FIG. 5A) and a portion of the fluorescent material 140 (labeled in FIG. 5A) are removed to form grooves 757 exposing a portion of the fluorescent material 340, and to form the reflective layer 550 (labeled in FIG. 7A) corresponding to and covering the light emitting units 110. For example, a portion of the reflective material 559 located between two adjacent light emitting units 110 and the corresponding fluorescent material 140 are removed by a suitable method (e.g., cutting or etching).

In the present embodiment, the fluorescent material 340 includes the low-concentration fluorescent material 342 and the high-concentration fluorescent material 341, and the grooves 357 expose a portion of the low-concentration fluorescent material 342.

Referring to FIG. 7A to FIG. 7B, similar to the steps of FIG. 5B to FIG. 5C, the light-absorbing material 569 is formed to cover at least the side surface 550c and the inwardly concave curved surface 550a of the reflective layer 550. The light-absorbing material 569 also covers the portion of the low-concentration fluorescent material 342 exposed by the grooves 357. The material or the forming method of the light-absorbing material 569 is the same as or similar to the light-absorbing material 169.

In an embodiment, when or after the colloid forming the light-absorbing material 569 is covered on the reflective layer 550, due to surface tension, the colloid covering the reflective layer 550 gradually approaches the fluorescent material 340 away from the light emitting units 110.

In an embodiment, the light-absorbing material 569 is formed between two adjacent light emitting units 110. Also, the light-absorbing material 569 located between the two light emitting units 110 has the corresponding inwardly concave outer surface 569a. The inwardly concave outer surface 569a is inwardly concave in the direction of the fluorescent material 340.

Referring to FIG. 7B to FIG. 7C, similar to the steps of FIG. 1H to FIG. 1I or FIG. 5C to FIG. 5D above, a portion of the light-absorbing material 569 (labeled in FIG. 7B) and a portion of the fluorescent material 340 (labeled in FIG. 5B) are removed to correspondingly form a light-absorbing layer 760 (labeled in FIG. 5C) and the fluorescent layer 330 (labeled in FIG. 5C). A portion of the light-absorbing material 569 located between two adjacent light emitting units 110 and the corresponding fluorescent material 340 are removed by a suitable method (e.g., cutting or etching). That is, the removed portion of the light-absorbing material 569 and the portion of the fluorescent material 340 at least correspond to the inwardly concave outer surface 569a.

After the above process, the manufacture of the light emitting device 701 of the seventh embodiment may be substantially completed.

Referring to FIG. 7C, the light emitting device 701 includes the light emitting units 110, the fluorescent layer 330, the reflective layer 550, and the light-absorbing layer 760. The light-absorbing layer 760 covers the side surface 550c and the inwardly concave curved surface 550a of the reflective layer 550. The side surface 550c is substantially parallel to the thickness direction D1 of the light emitting device 101. The inwardly concave curved surface 550a is substantially not parallel to the thickness direction D1 of the light emitting device 101. The reflective layer 550 is located between the side surface 110c of the light emitting units 110 and a portion of the light-absorbing layer 760. The bottom of the light-absorbing layer 760 has the inwardly concave curved surface 560a, and the inwardly concave curved surface 560a is concave toward the fluorescent layer 330 along a direction away from the light emitting units 11.

In the present embodiment, the bottom end (for example: in the thickness direction D1 of the light emitting device 101, where the light-absorbing layer 760 is farthest from the fluorescent layer 130) of the light-absorbing layer 760 is aligned (for example: located on a same horizontal plane, and the thickness direction D1 is substantially the normal direction of the horizontal plane) with the bottom end (for example: in the thickness direction D1 of the light emitting device 101, where the electrodes 112 are farthest from the fluorescent layer 130) of the electrodes 112 of the light emitting units 110.

In the present embodiment, the bottom end of the reflective layer 550 (e.g., where the reflective layer 550 is farthest from the fluorescent layer 130 in the thickness direction D1 of the light emitting device 101) is not aligned with the bottom end of the electrodes 112 of the light emitting units 110.

In the present embodiment, the fluorescent layer 330 includes the high-concentration fluorescent layer 331 and the low-concentration fluorescent layer 332. The light-absorbing layer 760 covers the high-concentration fluorescent layer 331 and the low-concentration fluorescent layer 332. For example, the light-absorbing layer 760 covers the side surface of the high-concentration fluorescent layer 331 and a portion of the side surface of the low-concentration fluorescent layer 332, and the light-absorbing layer 760 exposes at least a portion of the remaining side surface of the low-concentration fluorescent layer 332.

In the present embodiment, the light-absorbing layer 760 of the light emitting device 701 allows the light emitting device 701 to have better applicability.

In an embodiment, the light emitting device 701 is adaptively applied. Referring to FIG. 7D, similar to that shown in FIG. 1J, in an embodiment, the electrodes 112 of the light emitting units 110 are electrically connected to the circuit board 170, which is regarded as another form of a light emitting device 702 in the seventh embodiment. In other words, when understanding the light emitting device 702 in FIG. 7D, refer to the light emitting device 701 in FIG. 7C and its corresponding description or manufacturing method (e.g., FIG. 1A to FIG. 1E, FIG. 5A, and FIG. 7A to FIG. 7C).

Referring to FIG. 7D, the light emitting device 702 includes the light emitting units 110, the fluorescent layer 330, the reflective layer 550, the light-absorbing layer 760, and the circuit board 170.

In the present embodiment, in the thickness direction D1 of the light emitting device 702, the spacing between the reflective layer 550 and the circuit board 170 is gradually increased in a direction away from the light emitting units 110.

In the present embodiment, in the thickness direction D1 of the light emitting device 702, the spacing between the light-absorbing layer 760 and the circuit board 170 is gradually increased in a direction away from the light emitting units 110.

In the present embodiment, via the light-absorbing layer 760, the electrical connection yield between the electrodes 112 of the light emitting units 110 and the circuit board 170 is improved, thereby improving the light output quality of the light emitting device 702.

In the present embodiment, the light emitting quality of the light emitting device 701 or the light emitting device 702 is improved via the light-absorbing layer 760. For example, lateral light output is reduced; and/or light mixing phenomenon is reduced.

In the present embodiment, in the light emitting device 701 or the light emitting device 702, the high-concentration fluorescent layer 331 is closer to the light emitting units 110 than the low-concentration fluorescent layer 332. In this way, when activating the light emitting device 701 or the light emitting device 702, the generated heat is quickly dissipated via a thermally conductive member (e.g., the electrodes 112 formed of a metal material; or other metal materials electrically connected thereto).

In the present embodiment, the adhesive layer 120, the low-concentration fluorescent layer 331, the high-concentration fluorescent layer 332, the reflective layer 550, or the light-absorbing layer 760 are electrically insulating.

FIG. 8 is a schematic partial cross-sectional view of a light emitting device according to the eighth embodiment of the invention. The manufacturing method of a light emitting device 802 of the present embodiment is similar to the manufacturing method of the light emitting device (e.g., the light emitting devices 202 and 702, but not limited to) in the above embodiments, and similar members thereof are represented by the same reference numerals and have similar functions, materials, or forming methods, and are not repeated herein.

Referring to FIG. 8, the light emitting device 802 includes the light emitting units 110, the fluorescent layer 430, the reflective layer 550, and the light-absorbing layer 760. The fluorescent layer 430 is disposed on the top surface 110a of the light emitting units 110.

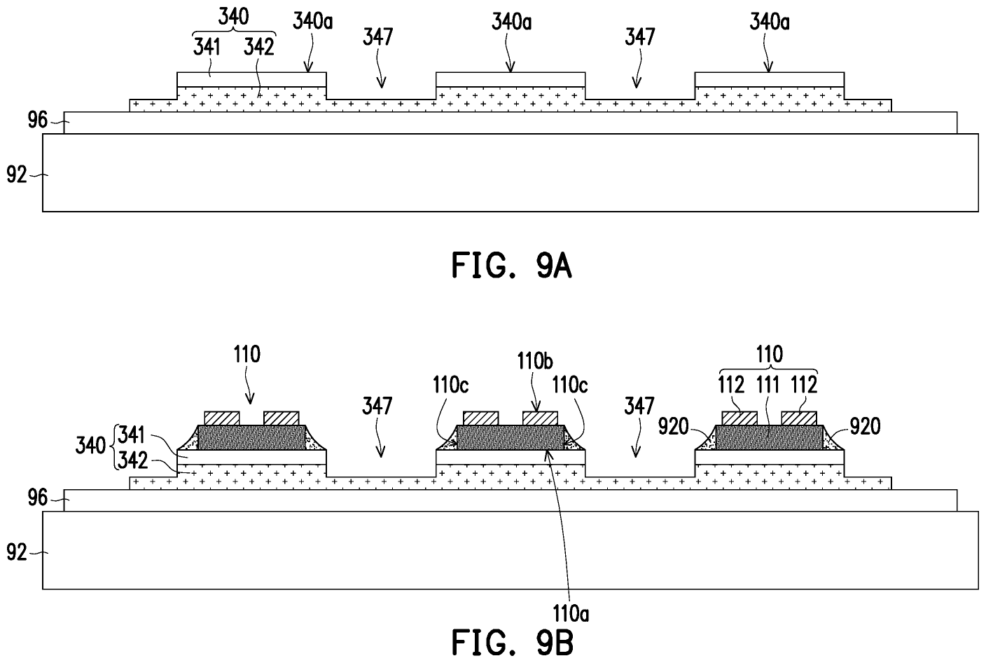

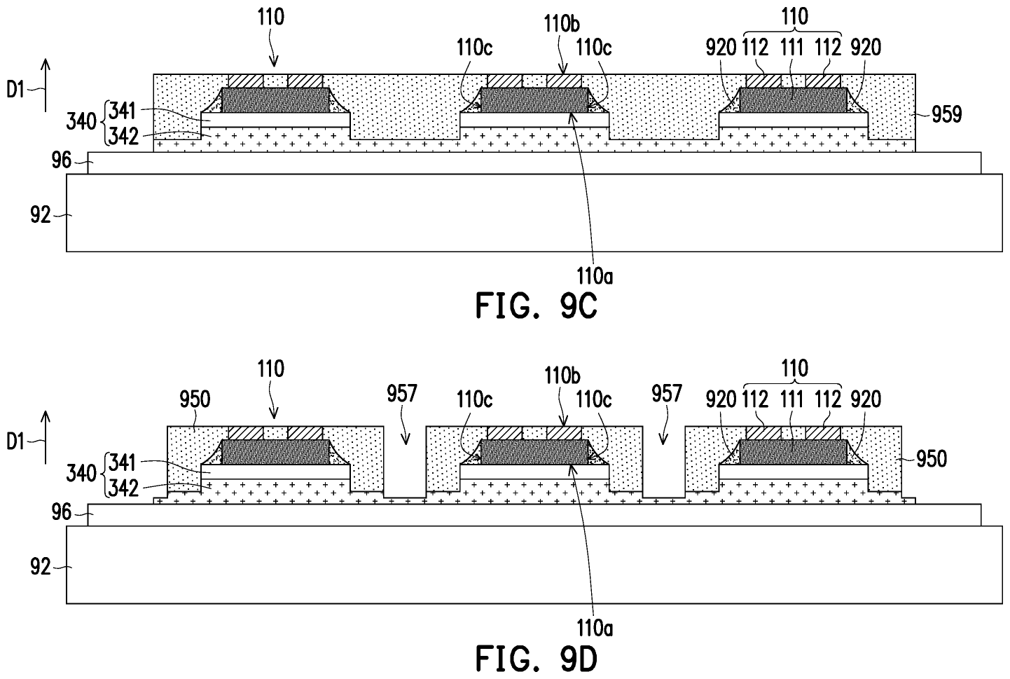

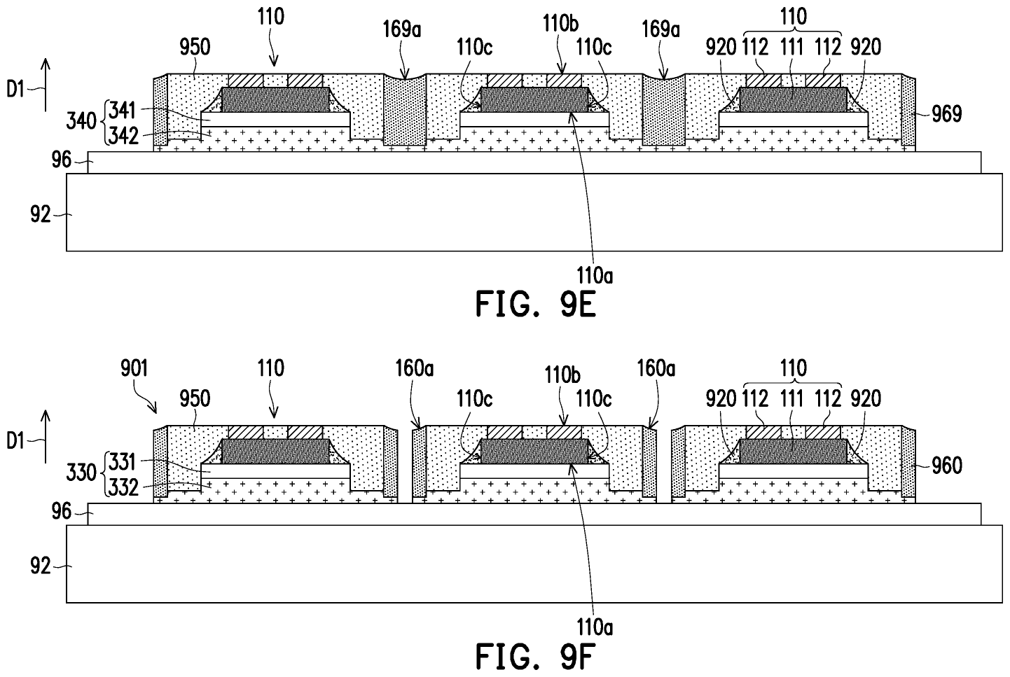

FIG. 9A to FIG. 9F are schematic partial cross-sectional views of a portion of a manufacturing method of a light emitting device 9 according to the ninth embodiment of the invention. The manufacturing method of a light emitting device 901 of the present embodiment is similar to the manufacturing method of the light emitting device (e.g., the light emitting device 101, but not limited to) in the above embodiments, and similar members thereof are represented by the same reference numerals and have similar functions, materials, or forming methods, and are not repeated herein. Specifically, FIG. 9A to FIG. 9F show schematic partial cross-sectional views illustrating a portion of a manufacturing method of the light emitting device 901 following the step of FIG. 1B.

Referring to FIG. 1B and FIG. 9A, a portion of the fluorescent material 140 (labeled in FIG. 1B) is removed to form the fluorescent material 340 (labeled in FIG. 9A) having a plurality of grooves 347 and a plurality of placement platforms 340a on the outer surface. The grooves 347 and the placement platforms 340a correspond to each other. For example, in the fluorescent material 340, the thickness at the placement platforms 340a is greater than where the grooves 347 are provided. The number or shape of the grooves 347 or the placement platforms 340a may be adjusted according to design requirements.

In the present embodiment, the grooves 347 expose a portion of the low-concentration fluorescent material 342.

Referring to FIG. 9A to FIG. 9B, the light emitting units 110 are disposed on the placement platforms 340a (labeled in FIG. 9A) of the fluorescent material 340. The light emitting units 110 and the fluorescent material 340 are combined via an adhesive layer 920. The material of the adhesive layer 920 is the same as or similar to the adhesive layer 120. The adhesive layer 920 covers at least the side surface 110c of the light emitting units 110 and the surface of the placement platforms 340a. In addition, due to surface tension, the colloid forming the adhesive layer 920 substantially (e.g., under a suitable amount of adhesive) does not overflow the placement platforms 340a and/or fill the grooves 347.

In an embodiment, after the light emitting units 110 and the fluorescent material 340 are bonded, there is still a portion of the adhesive material between the top surface 110a of the light emitting units 110 and the fluorescent material 340. For example, first, a suitable adhesive material is formed on the top surface 110a of the light emitting units 110, and then, the light emitting units 110 having the adhesive material on the top surface 110a thereof is adhered to the surface of the placement platforms 340a. In addition, the colloid forming a portion of the adhesive material is overflown to the side surface 110c of the light emitting units 110 (i.e., a surface between the top surface 110a and the bottom surface 110b) due to extrusion.

In an embodiment, after the light emitting units 110 and the fluorescent material 340 are bonded, the top surface 110a of the light emitting units 110 is directly in contact with the fluorescent material 340. For example, first, the light emitting units 110 are disposed on the placement platforms 340a with the top surface 110a of the light emitting units 110 facing the placement platforms 340a, then an adhesive material is formed on the side surface 110c of the light emitting units 110 via dispensing.

In an embodiment, the adhesive material is cured (e.g., heated and/or illuminated) at a suitable time and in a suitable manner. The cured adhesive material is called the adhesive layer 920.

Referring to FIG. 9B to FIG. 9C, similar to the steps of FIG. 1E to FIG. 1F, a reflective material 959 is formed on the fluorescent material 340 to cover the light emitting units 110. The material or the forming method of the reflective material 959 is the same as or similar to the reflective material 159.

Referring to FIG. 9C to FIG. 9D, similar to the steps of FIG. 1F to FIG. 1G, a portion of the reflective material 959 (labeled in FIG. 9C) is removed to form grooves 957 exposing a portion of the fluorescent material 340, and to form a reflective layer 950 (labeled in FIG. 9D) corresponding to and covering the light emitting units 110.

In the present embodiment, the grooves 957 expose a portion of the low-concentration fluorescent material 342.

In the present embodiment, during the process of removing a portion of the reflective material 959, a portion of the low-concentration fluorescent material 342 (e.g., a portion of the low-concentration fluorescent material 342 near where the reflective material 959 is removed) is slightly removed.

Referring to FIG. 9D to FIG. 9E, similar to the steps of FIG. 1G to FIG. 1H, a light-absorbing material 969 is formed to cover at least a side surface 950c of the reflective layer 950.

Referring to FIG. 9E to FIG. 9F, similar to the steps of FIG. 1H to FIG. 1I above, a portion of the light-absorbing material 969 (labeled in FIG. 9E) and a portion of the fluorescent material 340 (labeled in FIG. 9E) are removed to correspondingly form a light-absorbing layer 960 (labeled in FIG. 9F) and the fluorescent layer 330 (labeled in FIG. 9F). The removed portion of the light-absorbing material 969 and the portion of the fluorescent material 340 at least correspond to the inwardly concave outer surface 169a.

After the above process, the manufacture of the light emitting device 901 of the ninth embodiment may be substantially completed.

Referring to FIG. 9F, the light emitting device 901 includes the light emitting units 110, the fluorescent layer 330, the reflective layer 950, and the light-absorbing layer 960.

Referring to FIG. 9G, similar to that shown in FIG. 1J, in an embodiment, the electrodes 112 of the light emitting units 110 are electrically connected to the circuit board 170, which is regarded as another form of a light emitting device 902 in the ninth embodiment. In other words, when understanding the light emitting device 902 in FIG. 9G, refer to the light emitting device 101 in FIG. 9F and its corresponding description or manufacturing method (e.g., FIG. 1A to FIG. 1B and FIG. 9A to FIG. 9F).

Referring to FIG. 9G, the light emitting device 902 includes the light emitting units 110, the fluorescent layer 330, the reflective layer 950, the light-absorbing layer 160, and the circuit board 170.

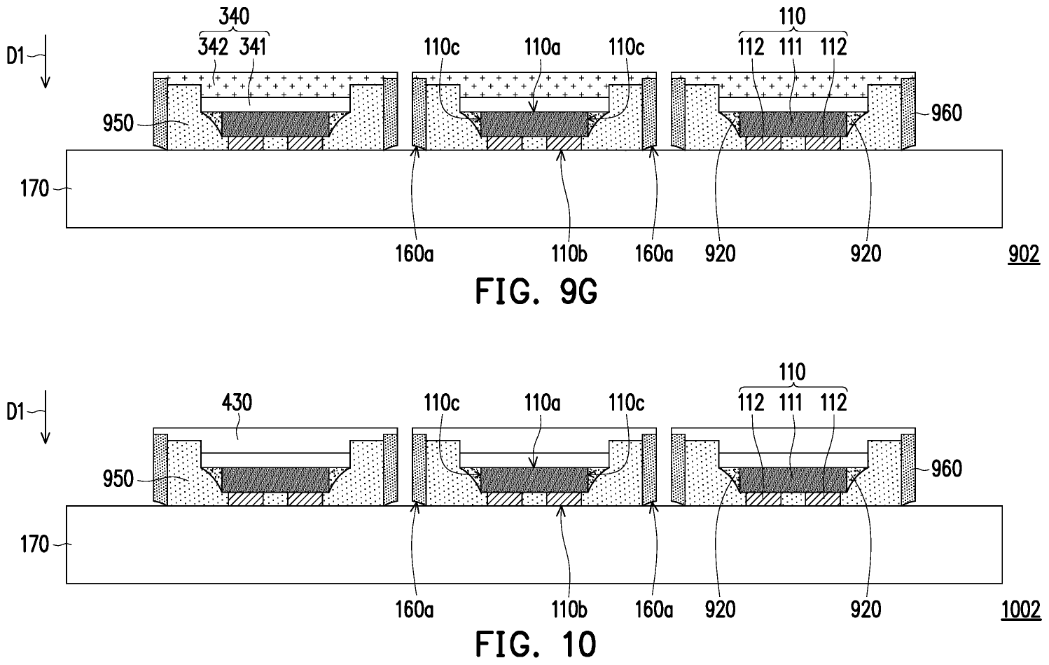

FIG. 10 is a schematic partial cross-sectional view of a light emitting device according to the tenth embodiment of the invention. The manufacturing method of a light emitting device 1002 of the present embodiment is similar to the manufacturing method of the light emitting device (e.g., the light emitting devices 202, 402, and 902, but not limited to) of the ninth embodiment, and similar members thereof are represented by the same reference numerals and have similar functions, materials, or forming methods, and are not repeated herein.

Referring to FIG. 10, a light emitting device 1102 includes the light emitting units 110, the fluorescent layer 430, the reflective layer 950, and the light-absorbing layer 160. The fluorescent layer 430 is disposed on the top surface 110a of the light emitting units 110.

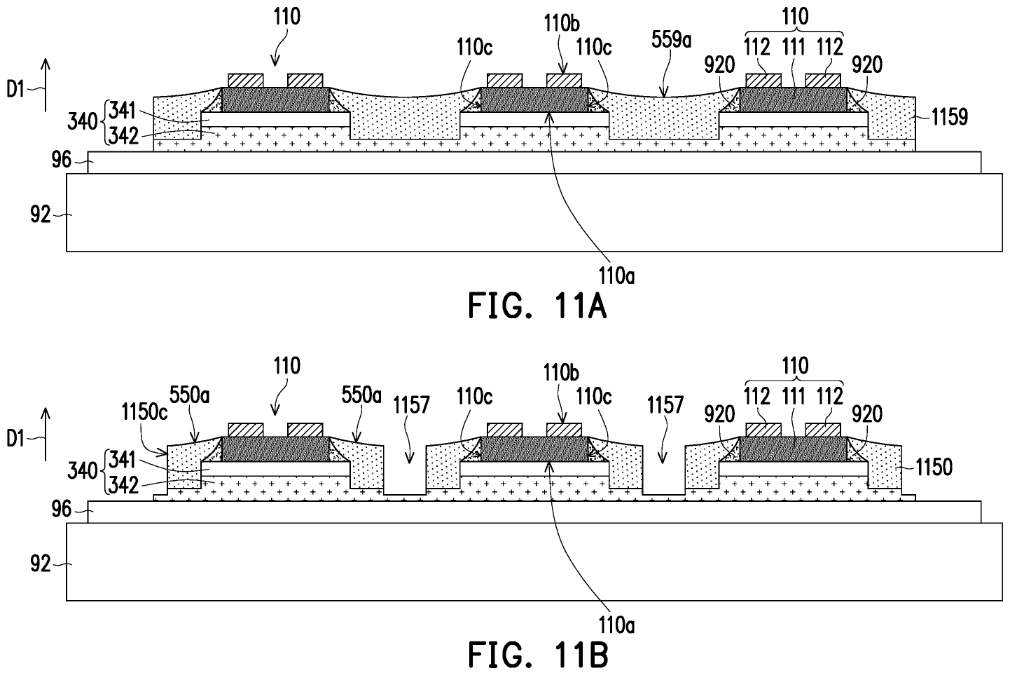

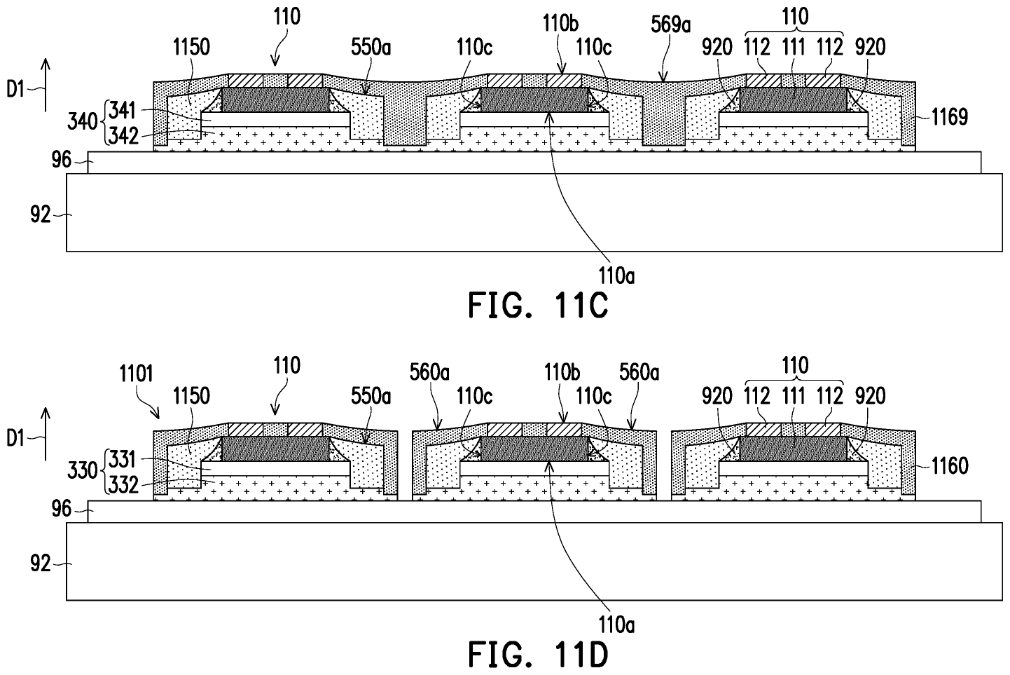

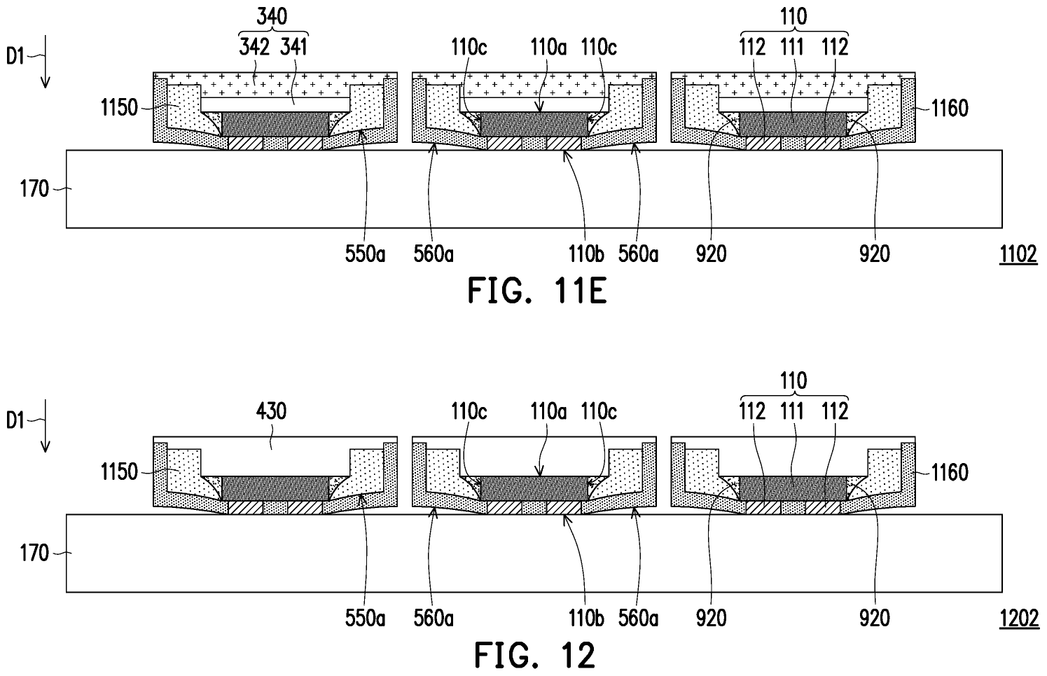

FIG. 11A to FIG. 11D are schematic partial cross-sectional views of a portion of a manufacturing method of a light emitting device according to the eleventh embodiment of the invention. The manufacturing method of a light emitting device 1101 of the present embodiment is similar to the manufacturing method of the light emitting device (e.g., the light emitting devices 101, 501, and 901, but not limited to) in the above embodiments, and similar members thereof are represented by the same reference numerals and have similar functions, materials, or forming methods, and are not repeated herein. Specifically, FIG. 11A to FIG. 11F show schematic partial cross-sectional views illustrating a portion of a manufacturing method of the light emitting device 1101 following the step of FIG. 9B.

Referring to FIG. 9B and FIG. 11A, similar to the steps of FIG. 9B to FIG. 9C, a reflective material 1159 is formed on the fluorescent material 340 to cover the light emitting units 110. The material or the forming method of the reflective material 1159 is the same as or similar to the reflective material 559.

In an embodiment, the reflective material 1159 is formed between two adjacent light emitting units 110. Also, the reflective material 1159 located between the two light emitting units 110 has the corresponding inwardly concave outer surface 559a. The inwardly concave outer surface 559a is inwardly concave in the direction of the fluorescent material 340.

Referring to FIG. 11A and FIG. 11B, similar to the steps of FIG. 9C to FIG. 9D, a portion of the reflective material 1159 (labeled in FIG. 11A) is removed to form grooves 1157 exposing a portion of the fluorescent material 340, and to form a reflective layer 1150 (labeled in FIG. 11B) corresponding to and covering the light emitting units 110.

In the present embodiment, the grooves 1157 expose a portion of the low-concentration fluorescent material 342.

Referring to FIG. 11B and FIG. 11C, similar to the steps of FIG. 5B to FIG. 5C, a light-absorbing material 1169 is formed to cover at least a side surface 1150c and the inwardly concave curved surface 550a of the reflective layer 1150. The material or the forming method of the light-absorbing material 1169 is the same as or similar to the light-absorbing material 569.

Referring to FIG. 11C and FIG. 11D, similar to the steps of FIG. 5C to FIG. 5D above, a portion of the light-absorbing material 1169 (labeled in FIG. 11C) and a portion of the fluorescent material 340 (labeled in FIG. 11C) are removed to correspondingly form a light-absorbing layer 1160 (labeled in FIG. 11D) and the fluorescent layer 330 (labeled in FIG. 11D). A portion of the light-absorbing material 1169 located between two adjacent light emitting units 110 and the corresponding fluorescent material 340 are removed by a suitable method (e.g., cutting or etching). That is, the removed portion of the light-absorbing material 1169 and the portion of the fluorescent material 340 at least correspond to the inwardly concave outer surface 569a.

After the above process, the manufacture of the light emitting device 1101 of the eleventh embodiment may be substantially completed.

Referring to FIG. 11D, the light emitting device 1101 includes the light emitting units 110, the fluorescent layer 330, the reflective layer 1150, and the light-absorbing layer 1160. The light-absorbing layer 1160 covers the side surface 150c and the inwardly concave curved surface 550a of the reflective layer 1150. The reflective layer 1150 is located between the side surface 110c of the light emitting units 110 and a portion of the light-absorbing layer 1160.

Referring to FIG. 11E, similar to that shown in FIG. 1J, in an embodiment, the electrodes 112 of the light emitting units 110 are electrically connected to the circuit board 170, which is regarded as another form of the light emitting device 1102 in the eleventh embodiment. In other words, when understanding the light emitting device 1102 in FIG. 11E, refer to the light emitting device 1101 in FIG. 11D and its corresponding description or manufacturing method (e.g., FIG. 1A to FIG. 1B, FIG. 9A to FIG. 9B, and FIG. 11A to FIG. 11D).

Referring to FIG. 11E, the light emitting device 1102 includes the light emitting units 110, the fluorescent layer 330, the reflective layer 1150, the light-absorbing layer 1160, and the circuit board 170.

FIG. 12 is a schematic partial cross-sectional view of a light emitting device according to the twelfth embodiment of the invention. The manufacturing method of a light emitting device 1202 of the present embodiment is similar to the manufacturing method of the light emitting device (e.g., the light emitting devices 202, 402, and 1102, but not limited to) in the above embodiments, and similar members thereof are represented by the same reference numerals and have similar functions, materials, or forming methods, and are not repeated herein.

Referring to FIG. 12, the light emitting device 1102 includes the light emitting units 110, the fluorescent layer 430, the reflective layer 1150, and the light-absorbing layer 1160. The fluorescent layer 430 is disposed on the top surface 110a of the light emitting units 110.

Based on the above, the light emitting unit of the invention has better light emitting quality, and/or the light emitting device manufactured by the manufacturing method of the light emitting device of the invention has better light emitting quality.

What is claimed is:

1. A light emitting device, comprising:
a light emitting unit having a top surface, a bottom surface opposite to the top surface, and a side surface located between the top surface and the bottom surface, and the light emitting unit comprises an electrode disposed at the bottom surface;
a fluorescent layer disposed on the top surface of the light emitting unit;
a reflective layer covering the side surface of the light emitting unit; and
a light-absorbing layer covering the reflective layer, so that the reflective layer is located between the side surface of the light emitting unit and the light-absorbing layer.

2. The light emitting device of claim 1, wherein a bottom end of the light-absorbing layer is aligned with a bottom end of the electrode of the light emitting unit.

3. The light emitting device of claim 1, wherein a bottom of the light-absorbing layer has an inwardly concave curved surface, and the inwardly concave curved surface is concave toward the light-absorbing layer along a direction away from the light emitting unit.

4. The light emitting device of claim 1, wherein in a thickness direction of the light emitting device, a distance between the light-absorbing layer and the fluorescent layer is gradually decreased along a direction away from the light emitting unit.

5. The light emitting device of claim 1, further comprising:
a circuit board, wherein the bottom surface of the light emitting unit faces the circuit board, and the electrode is electrically connected to the circuit board.

6. The light emitting device of claim 5, wherein in a thickness direction of the light emitting device, a distance between the light-absorbing layer and the circuit board is gradually increased along a direction away from the light emitting unit.

7. The light emitting device of claim 1, further comprising:
an adhesive layer covering the side surface of the light emitting unit, and the adhesive layer is located between the side surface of the light emitting unit and the reflective layer.

8. The light emitting device of claim 1, wherein a bottom of the reflective layer has an inwardly concave curved surface, and the inwardly concave curved surface is concave toward the light-absorbing layer along a direction away from the light emitting unit.

9. The light emitting device of claim 8, wherein in a thickness direction of the light emitting device, a thickness of a portion of the reflective layer located between the adhesive layer and the light-absorbing layer is gradually increased along the direction away from the light emitting unit.

10. The light emitting device of claim 1, wherein the fluorescent layer further comprises a low-concentration fluorescent layer and a high-concentration fluorescent layer stacked on each other, and the high-concentration fluorescent layer is located between the light emitting unit and the low-concentration fluorescent layer.

11. A manufacturing method of a light emitting device, comprising:
providing a light emitting unit having a top surface, a bottom surface opposite to the top surface, and a side surface located between the top surface and the bottom surface, and the light emitting unit comprises an electrode disposed at the bottom surface;
disposing the light emitting unit on a fluorescent material, so that the top surface of the light emitting unit faces the fluorescent material;
forming a reflective layer covering the side surface of the light emitting unit; and
forming a light-absorbing layer to cover the reflective layer, so that the reflective layer is located between the side surface of the light emitting unit and the light-absorbing layer.

12. The manufacturing method of the light emitting device of claim 11, wherein the step of disposing the light emitting unit on the fluorescent material and the step of forming the reflective layer comprise:
disposing a plurality of the light emitting units on the fluorescent material;
forming a reflective material on the fluorescent material to cover a plurality of the light emitting units; and
removing a portion of the reflective material to form a plurality of the reflective layer corresponding to and covering each of the light emitting units.

13. The manufacturing method of the light emitting device of claim 12, wherein the reflective material has an inwardly concave outer surface inwardly concave toward a direction of the fluorescent material.

14. The manufacturing method of the light emitting device of claim 13, wherein the removed portion of the reflective material corresponds to at least the inwardly concave outer surface.

15. The manufacturing method of the light emitting device of claim 12, wherein the step of forming the light-absorbing layer comprises:
forming a light-absorbing material between a plurality of the reflective layer; and
removing a portion of the light-absorbing material to form a plurality of the light-absorbing layer corresponding to each of the light emitting units and covering each of the reflective layers, and the manufacturing method of the light emitting device further comprises:
removing a portion of the fluorescent material after the light-absorbing material is formed to form a plurality of fluorescent layers corresponding to each of the light emitting units.

16. The manufacturing method of the light emitting device of claim 15, wherein the light-absorbing material has an inwardly concave outer surface inwardly concave toward a direction of the fluorescent material.

17. The manufacturing method of the light emitting device of claim 16, wherein the removed portion of the light-absorbing material corresponds to at least the inwardly concave outer surface.

18. The manufacturing method of the light emitting device of claim 11, further comprising:
forming an adhesive layer, so that the light emitting unit and the fluorescent material are combined at least via the adhesive layer.
